(19) United States
(12) Patent Application Publication
(10) Pub. No.: US 2014/0299978 A1
(43) Pub. Date: Oct. 9, 2014

(54) QUAD FLAT NON-LEAD PACKAGE

(71) Applicant: LINGSEN PRECISION INDUSTRIES, LTD., TAICHUNG CITY (TW)

(72) Inventor: Mu-Tsan LIAO, TAICHUNG CITY (TW)

(73) Assignee: LINGSEN PRECISION INDUSTRIES, LTD., TAICHUNG CITY (TW)

(21) Appl. No.: 14/244,352

(22) Filed: May 30, 2014

(30) Foreign Application Priority Data
Apr. 3, 2013 (TW) 1022062 11

(51) Int. Cl. H01L 23/495; H01L 23/31

(52) U.S. Cl. CPC H01L 23/4952; H01L 23/3114
USPC 257/670

(57) ABSTRACT

A quad flat non-lead package includes a chip, a chip carrier including a bearing surface adapted for the mounting of the chip, a plurality of leads mounted around the chip carrier and electrically connected to the chip, each lead having an opening located in an outer edge of a rear end thereof, and a molding compound formed on the chip, the chip carrier and the leads by compression molding to let the opening of each lead be exposed to the outside. The design of the openings of the leads can provide more tin-climbing area to improve soldering quality and yield, thereby lowering the manufacturing cost and facilitating testing after the soldering process. The invention also provides a lead frame for quad flat non-lead package.

### BACKGROUND OF THE INVENTION

1. Field of the Invention

The present invention relates to semiconductor packaging technology and more particularly, to a quad flat non-lead package that provides more tin-climbing area to improve soldering quality and yield, thereby lowering the manufacturing cost and facilitating testing after the soldering process.

2. Description of the Related Art

In the IC packaging industry, a bare chip is an integrated circuit made through wafer fabrication, circuit design, mask making and wafer dicing processes. Every bare chip is cut out from the wafer. A chip package is constructed by means of electrically connecting bonding pads at the bare chip and the substrate and then encapsulating the bare chip with a molding compound. The purpose of packaging is to protect the bare chip against interferences of the external environment and dust pollution of miscellaneous and also to enhance the electrically connected intermediary between the bare chip and the external circuit.

FIGS. 1 and 2 illustrate a quad flat non-lead package according to the prior art. According to this prior art design, the package 1 comprises a chip 2, a chip carrier 3, a plurality of leads 4, a plurality of lead wires 5 and a molding compound 6. The chip 2 is arranged on the top side of the chip carrier 3. The leads 4 are arranged around the chip carrier 3. Further, the chip 2 is electrically connected with the leads 4 using wire bonding techniques. At final, the molding compound 6 is molded on the chip 2, the chip carrier 3, the leads 4 and the lead wires 5 for protection.

Further, the bottom surface of each lead of this prior art quad flat non-lead package is not encapsulated in the molding compound. Further, the end edges of the leads of this prior art quad flat non-lead package are kept in flush in the four sides of the molding compound to serve as external contacts of the quad flat non-lead package.

However, because the leads of this prior art quad flat non-lead package are kept in flush in the four sides of the molding compound, the applied tin solder is located at the bottom side of the package during the SMD manufacturing process, complicating the test of the chip after the soldering process. Further, because the tin-climbing area is limited to the bottom surface areas of the leads, the soldering quality of this design of quad flat non-lead package cannot be upgraded subject to the constraint of insufficient tin-climbing area.

In view of this, U.S. Pat. No. 6,608,366 discloses an improved design entitled “Lead frame with plated end leads”, as shown in FIGS. 3 and 4. The structure of this package 1′ is substantially similar to the aforesaid prior design with the exception that each lead 4′ has a recess 7 formed in a bottom surface thereof by half-etching process. Using this recess to increase the tin-climbing area between the tin solder 9 and the leads 4′ can improve the reliability of the soldering points.

In the aforesaid patent, the design of the recesses of the leads can increase the tin-climbing area. However, this design causes the applied tin solder to be located on the bottom side of the package, complicating the testing of the chip after the SMD manufacturing process. Further, the recesses of the leads of this patent are formed by half-etching process. When compared to the aforesaid prior art quad flat non-lead package, the manufacturing of this patent is complicated, relatively increasing the cost.

In conclusion, the conventional package designs have drawbacks, leaving room for improvement.

### SUMMARY OF THE INVENTION

The present invention has been accomplished under the circumstances in view. It is the main object of the present invention to provide a quad flat non-lead package, which provides more tin-climbing area to improve soldering quality and yield, thereby lowering the manufacturing cost and facilitating testing after the soldering process.

To achieve this and other objects of the present invention, a quad flat non-lead package of the invention comprises a chip, a chip carrier including a bearing surface adapted for the mounting of the chip, a plurality of leads mounted around the chip carrier and electrically connected to the chip, each lead having an opening located in an outer edge of a rear end thereof, a plurality of cutting paths respectively defined corresponding to the openings of the leads and a molding compound formed on the chip, the chip carrier and the leads by compression molding to let the opening of each lead be exposed to the outside.

Preferably, the opening of each lead is a through hole formed by metal stamping.

Preferably, the opening of each lead is smoothly arched.

Preferably, the molding compound is individually formed by compress molding.

Preferably, the leads are respectively electrically connected to the chip by wire bonding.

To achieve this and other objects of the present invention, a quad flat non-lead package of the present invention comprises a plurality of lead frames. Each lead frame comprises a chip, a chip carrier including a bearing surface adapted for the mounting of the chip, a plurality of leads mounted around the chip carrier and electrically connected to the chip, each lead having an opening located in an outer edge of a rear end thereof, a plurality of cutting paths respectively defined corresponding to the openings of the leads, and a molding compound formed on the chip, the chip carrier and the leads by compression molding to let the opening of each lead be exposed to the outside.

Preferably, the opening of each lead is a through hole formed by metal stamping.

Further, the lead frames are arranged in an array.

Preferably, the molding compound is individually formed by compress molding.

Preferably, the leads are respectively electrically connected to the chip by wire bonding.

Subject to the design of the opening of each lead and individual formation of the molding compound by compress molding, the invention provides more tin-climbing area to improve soldering quality and yield, thereby lowering the manufacturing cost and facilitating testing after the soldering process.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is schematic sectional view of a quad flat non-lead package according to the prior art.

FIG. 2 is a bottom view of the quad flat non-lead package according to the prior art.

FIG. 3 is an oblique top elevational view of the quad flat non-lead package according to the prior art.

FIG. 4 is schematic sectional view of a part of the quad flat non-lead package according to the prior art, illustrating the configuration of the tin-climbing area of each lead.

FIG. 5 is a schematic sectional view of a quad flat non-lead package in accordance with the present invention.

FIG. 6 is a top view of the quad flat non-lead package in accordance with the present invention.

FIG. 7 is a schematic sectional view of a part of the quad flat non-lead package in accordance with the present invention, illustrating the configuration of the tin-climbing area of each lead.

FIG. 8 is a schematic sectional view of a quad flat non-lead package array in a lead frame in accordance with the present invention.

FIG. 9 is a top view of the quad flat non-lead package array in the lead frame in accordance with the present invention, illustrating the relative positioning between the cutting paths and the lead frame and the leads.

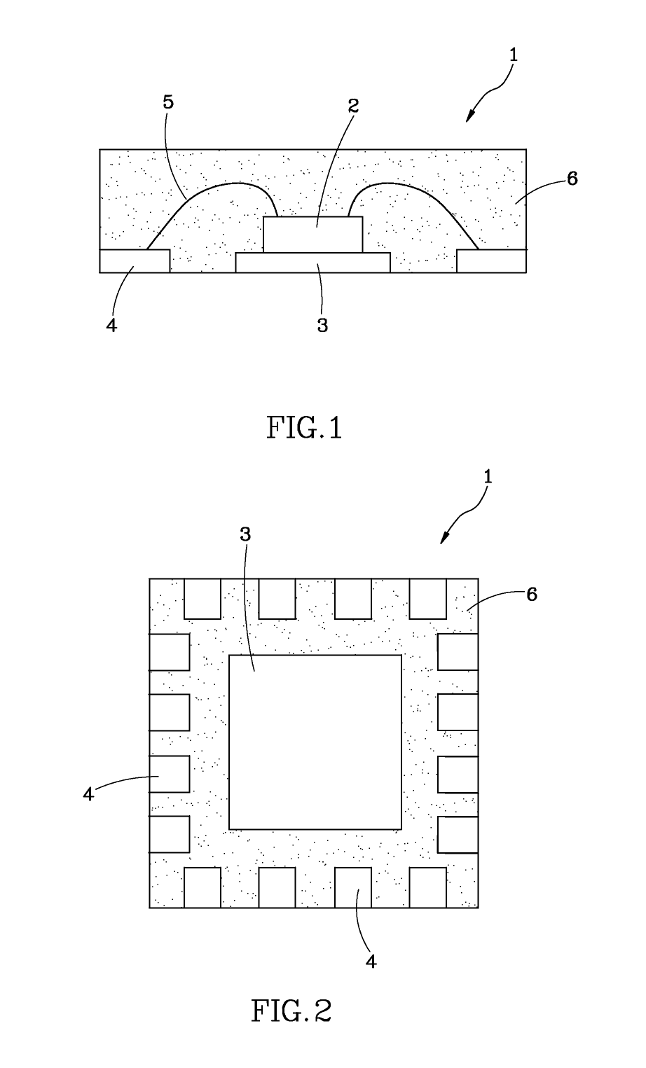

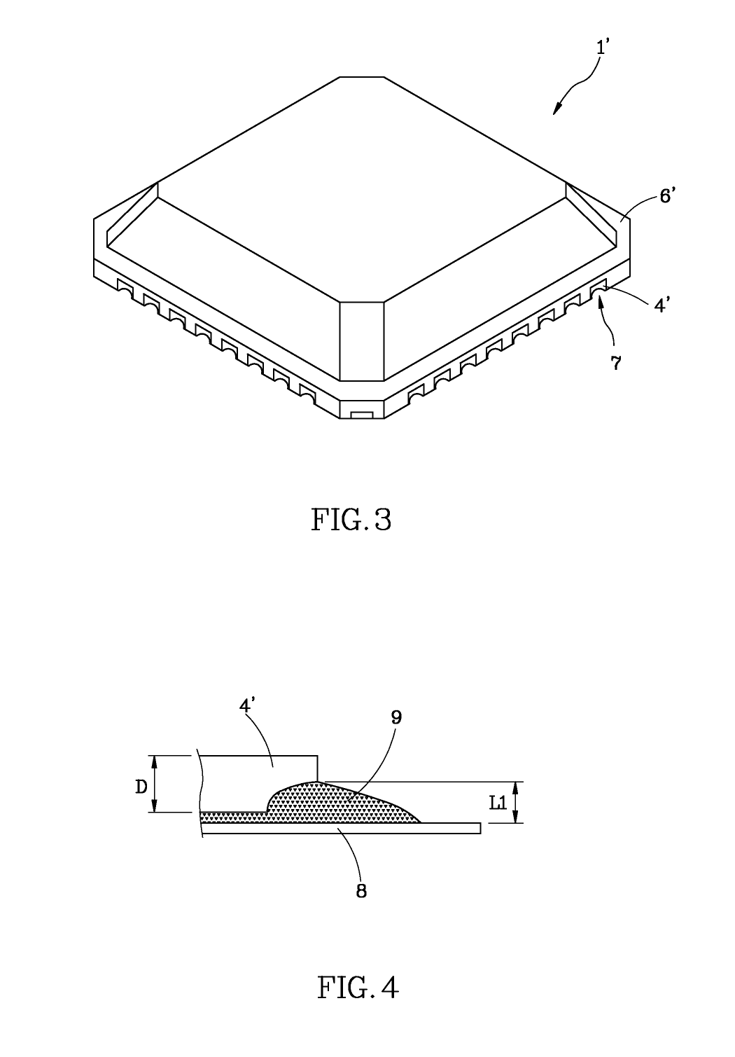

### DETAILED DESCRIPTION OF THE INVENTION

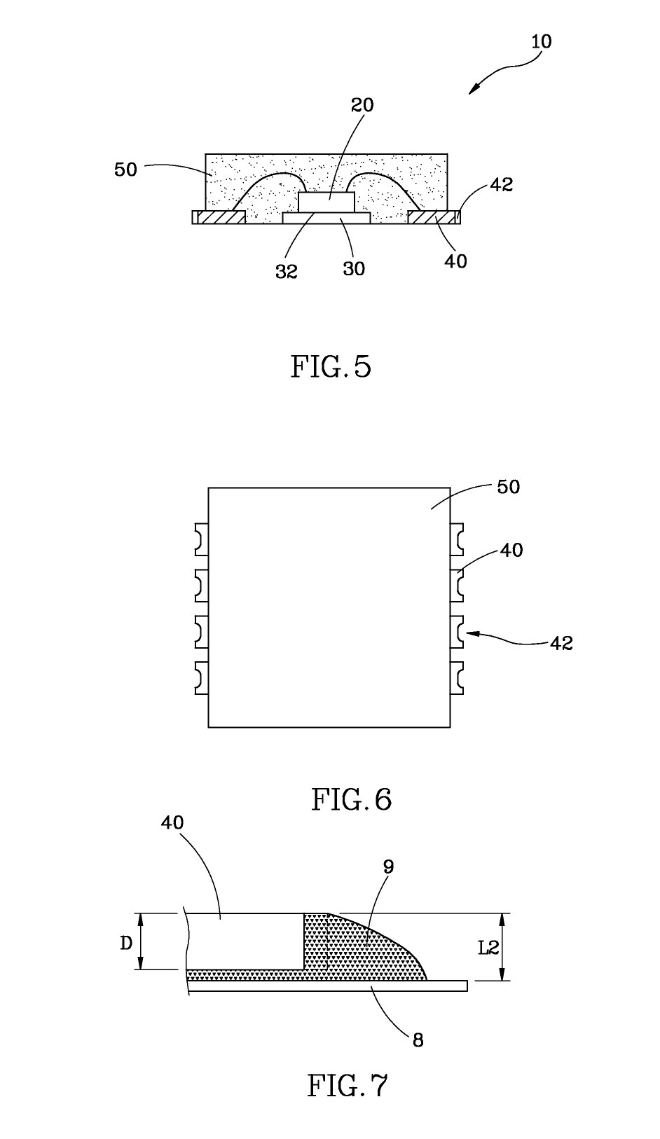

Referring to FIGS. 5-7, a quad flat non-lead package 10 in accordance with the present invention is shown. The quad flat non-lead package 10 comprises a chip 20, a chip carrier 30, a plurality of leads 40 and a molding compound 50.

The chip carrier 30 defines a bearing surface 32 for the mounting of the chip 20.

The leads 40 are arranged around the chip carrier 30 and respectively electrically connected to the chip 20 using wire bonding technique, each having an opening 42 located in an outer edge of a rear end thereof. The opening 42 is a arched through hole formed using basic metal stamping techniques, providing more tin-climbing area and enabling the production cost to be reduced.

The molding compound 50 is individually formed on the chip 20, the chip carrier 30 and the leads 40 by compression molding, enabling the opening 42 of each lead 40 to be exposed to the outside of the molding compound 50.

Therefore, as shown in FIG. 4 and FIG. 7, when compared to the SMD manufacturing process of the prior art quad flat non-lead package, the tin-climbing area between the tin solder 9 and each lead 40 in accordance with the present invention includes the bottom surface of each lead 40 and also the area around the opening 42 of each lead 40, i.e., the tin solder 9 will climb to the outer side of each lead 40 to fill up the opening 42 of each lead 40 subject to the siphon effect, thereby improving soldering quality and yield. If under the condition that the leads 4′ of the prior art design and the leads 40 of the present invention have the same thickness D, the recesses 7′ of the leads 4′ of the quad flat non-lead package 1′ of the prior art design are kept in the inner side of the molding compound 6′ in a flush manner, thus, the recess 4′ of each lead 4′ of the prior art design cannot be made in the form of a through hole, consequently, the tin-climbing height L1 of the leads 4′ for the tin solder 9 is about one half of the thickness of the leads 4′ (the distance between the top edge of the recess 7 and the substrate 8) is simply about one half of the thickness D of the leads 4′, and the tin-climbing area of the tin solder 9 is limited to the bottom side of the leads 4′.

In the structure of the present invention, the leads 40 extend to the outside of the molding compound 50, therefore, the opening 42 of each lead 40 can be made in the form of a through hole, consequently, the tin-climbing height L2 of the opening 42 is equal to the thickness D of the leads 40. Therefore, when compared to the package 1′ of the prior art design, the package 10 of the present invention provides more tin-climbing area to improve soldering quality and yield.

Further, the outer ends of the leads 40 of the quad flat non-lead package 10 of the present invention and the openings 42 of the leads 40 are exposed to the outside of the molding compound 50. Thus, in the test after the SMD manufacturing process, the quality of the tin solder 9 can be checked by a simple optical instrument without using an expensive X-Ray equipment, or through a destructive test such as micro-section or red dye penetration test. Thus, the invention facilitates testing after the soldering process of the tin solder 9, and reduces the testing cost.

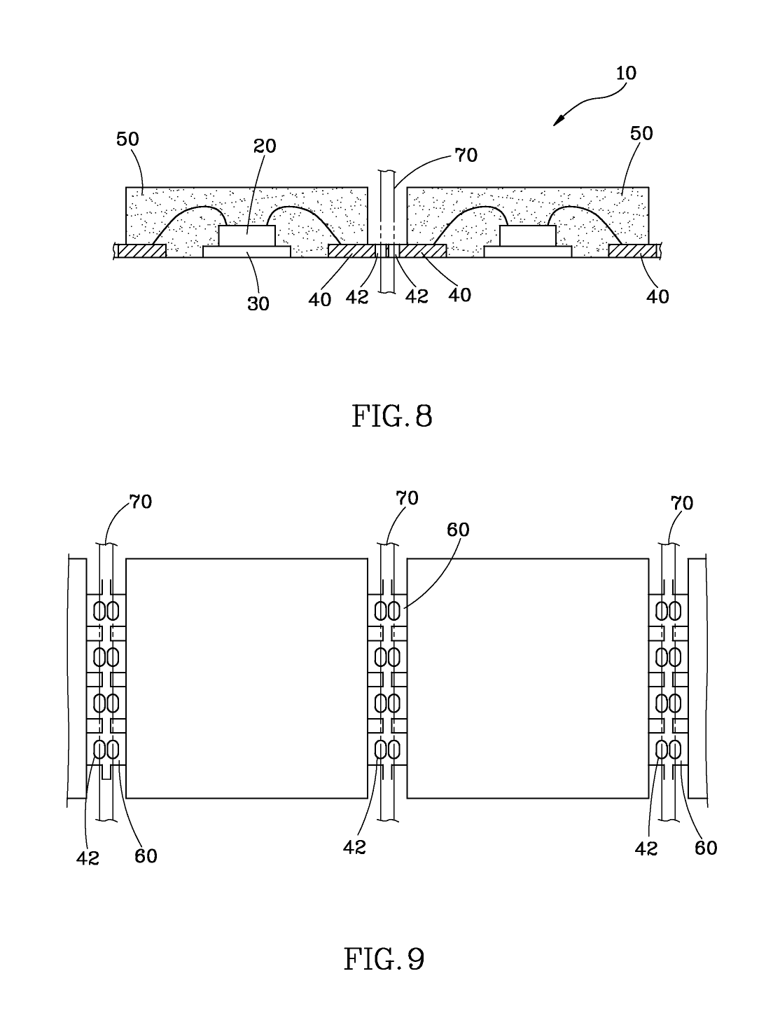

Referring to FIGS. 8 and 9, a lead frame 60 comprising an array of lead frame units for quad flat non-lead package in accordance with the present invention is shown, wherein each package 10 comprises a chip 20, a chip carrier 30, a plurality of leads 40, a plurality of cutting paths 70 and a molding compound 50. The chip carrier 30 comprises a bearing surface 32 for the mounting of the chip 20. The leads 40 are arranged around the chip carrier 30, and electrically connected to the chip 20 by wire bonding. Each lead 40 has an opening 42 located in an outer end thereof. The cutting paths 70 are respectively disposed corresponding to the openings 42 of the leads 40. The molding compound 50 is individually formed on the chip 20, the chip carrier 30 and the leads 40 by compress molding, enabling the openings 42 of the leads 40 to be exposed to the outside of the molding compound 50.

In detail, a metal stamping technique is applied to the lead frame 60 to make openings 42 in the leads 40 in each cutting path 70. Thereafter, each chip 20 is bonded to the associating chip carrier 30, and then electrically connected with the associating leads 40 by wire bonding, and then a respective molding compound 50 is individually formed on the associating chip 20, chip carrier 30 and lead frame 60 by compression molding to protect the associating chip 20 against external dust and moisture, and then a cutting or stamping technique is employed to the lead frame 60 along the cutting paths 70 to cut the finished product into multiple quad flat non-lead packages 10.

In other words, when compared to the conventional array-based compression molding, the individual compress molding method of the present invention are better to meet different packaging requirements. For example, a molding tool for array-based compression molding is simply applicable to one particular package arrangement. For different package arrangements, different molding tools shall be used to meet the needs. In comparison with the prior art design, the invention fits different array arrangements. Further, because the molding compound 50 is formed individually by compression molding, the level of packaging difficulty is relatively lowered, and thus the package manufacturing cost is relatively reduced.

In conclusion, the quad flat non-lead package of the present invention has the advantages as follows:

Each lead 40 has an opening 42 in the outer edge of the outer end thereof capable of providing more tin-climbing area to improve soldering quality and yield.

The openings 42 of the leads 40 are exposed to the outside of the molding compound 50. This arrangement facilitates testing after the soldering process of the tin solder 9.

Further, the opening 42 is formed by metal stamping, and the molding compound 50 is individually formed on the lead frame 60 by compression molding.

Thus, the invention can reduce the manufacturing cost and meets different package arrangement needs.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A quad flat non-lead package, comprising:
a chip;
a chip carrier comprising a bearing surface adapted for the mounting of said chip;
a plurality of leads mounted around said chip carrier and electrically connected to said chip, each said lead comprising an opening located in an outer edge of a rear end thereof; and
a molding compound formed on said chip, said chip carrier and said leads by compression molding to let the opening of each said lead be exposed to the outside of said molding compound.

2. The quad flat non-lead package as claimed in claim 1, wherein the opening of each said lead is a through hole formed by metal stamping.

3. The quad flat non-lead package as claimed in claim 2, wherein the opening of each said lead is smoothly arched.

4. The quad flat non-lead package as claimed in claim 1, wherein said molding compound is individually formed by compress molding.

5. The quad flat non-lead package as claimed in claim 1, wherein said leads are respectively electrically connected to said chip by wire bonding.

6. A quad flat non-lead package, comprising a plurality of lead frame units, each said lead frame unit comprising:
a chip;
a chip carrier comprising a bearing surface for the mounting of said chip;
a plurality of leads arranged around said chip carrier and respectively electrically connected to said chip, each said lead comprising an opening in an outer edge of an outer end thereof;
a plurality of cutting paths respectively defined corresponding to the openings of said leads; and
a molding compound formed on said chip, said chip carrier and said leads by compression molding to let the openings of said leads be exposed to the outside of said molding compound.

7. The quad flat non-lead package as claimed in claim 6, wherein the opening of each said lead is a through hole formed by metal stamping.

8. The quad flat non-lead package as claimed in claim 6, wherein said lead frame units of said lead frame are arranged in an array.

9. The quad flat non-lead package as claimed in claim 8, wherein said molding compound is individually formed by compress molding.

10. The quad flat non-lead package as claimed in claim 6, wherein said leads are respectively electrically connected to said chip by wire bonding.
